(19) United States
(12) Patent Application Publication
(10) Pub. No.: US 2018/0033659 A1
(43) Pub. Date: Feb. 1, 2018

(54) GAS PURGE SYSTEM AND METHOD FOR OUTGASSING CONTROL

(71) Applicant: Applied Materials, Inc., Santa Clara, CA (US)

(72) Inventors: Chun YAN, San Jose, CA (US); Xinyu BAO, Fremont, CA (US)

(21) Appl. No.: 15/414,326

(22) Filed: Jan. 24, 2017

Related U.S. Application Data
(60) Provisional application No. 62/368,066, filed on Jul. 28, 2016.

(51) Int. Cl. H01L 21/67; B08B 15/00; C30B 33/00; C30B 25/12; C30B 25/08; C30B 25/14

(52) U.S. Cl. CPC H01L 21/67201; C30B 25/08; C30B 25/14; C30B 33/00; C30B 25/12; B08B 15/00; B08B 2215/003

(57) ABSTRACT

Embodiments disclosed herein generally relate to a system, method, and apparatus for controlling substrate outgassing such that hazardous gasses are eliminated from a surface of a substrate after a III-V epitaxial growth process or an etch clean process, and prior to additional processing. An oxygen containing gas is flowed to a substrate in a load lock chamber, and subsequently a non-reactive gas is flowed to the substrate in the load lock chamber. As such, hazardous gases and outgassing residuals are decreased and/or removed from the substrate such that further processing may be performed.

### CROSS-REFERENCE TO RELATED APPLICATIONS

This application claims benefit of U.S. provisional patent application Ser. No. 62/368,066, filed Jul. 28, 2016, which is hereby incorporated herein by reference.

### BACKGROUND

### Field of the Disclosure

Embodiments of the present disclosure generally relate to the fabrication of integrated circuits. More specifically, embodiments disclosed herein relate to systems, methods, and apparatus for controlling substrate outgassing.

### Description of the Related Art

The manufacture of modern logic, memory, or integrated circuits typically involves more than four hundred process steps. A number of these steps are thermal processes that raise the temperature of the semiconductor substrate to a target value to induce rearrangement in the atomic order or chemistry of thin surface films (e.g., diffusion, oxidation, recrystallization, salicidation, densification, flow).

Ion implantation is a method for the introduction of chemical impurities in semiconductor substrates to form the p-n junctions necessary for field effect or bipolar transistor fabrication. Such impurities include P-type dopants, such as boron, aluminum, gallium, beryllium, magnesium, and zinc, and N-type dopants such as phosphorus, arsenic, antimony, bismuth, selenium, and tellurium. Ion implantation of chemical impurities disrupts the crystallinity of the semiconductor substrate over the range of the implant. At low energies, relatively little damage occurs to the substrate. However, the implanted dopants will not come to rest on electrically active sites in the substrate. Therefore, an anneal is necessary to restore the crystallinity of the substrate and drive the implanted dopants onto electrically active crystal sites.

During the processing of the substrate in, for example, an RTP chamber, the substrate may tend to outgas impurities implanted therein. These outgassed impurities may be the dopant material, a material derived from the dopant material, or any other material that may escape the substrate during the annealing process, such as the sublimation of silicon. The outgassed impurities may deposit on the colder walls and on the reflector plate of the chamber. This deposition may interfere with temperature pyrometer readings and with the radiation distribution fields on the substrate, which in turn affects the temperature at which the substrate is annealed. Deposition of the outgassed impurities may also cause unwanted particles on the substrates and may also generate slip lines on the substrate. Depending on the chemical composition of the deposits, the chamber is taken offline for a wet clean process.

Furthermore, one of the biggest challenges for III-V CMOS (FinFET, TFET) mass production is to control the outgassing from the substrates after a III-V epitaxial growth process and/or an etch clean process. Limitations in current outgassing control include that the thermal back process (>200 degrees Celsius) in either a process chamber or an etch chamber is not suitable after a III-V epitaxial growth or etch process as longer bake times for each substrate is necessary to drive out arsenic related outgassing gasses from the substrate surface and throughput is lowered. Furthermore, a long N₂ purge/pump cycle is less efficient and has a large impact on throughput. Testing has been performed on the prior known methods and results indicate that after ten cycles of pump/purge, arsenic outgassing was still detected at 1.9 parts per billion.

Absolute zero parts per billion (ppb) outgassing is typically desired for arsenic residuals due to arsenic toxicity. To minimize toxicity from arsenic outgassing during subsequent handling and processing of substrates, there is a need for an improved system, method, and apparatus for controlling substrate outgassing.

### SUMMARY

Embodiments disclosed herein generally relate to a system, method, and apparatus for controlling substrate outgassing such that hazardous gasses are eliminated from a surface of a substrate after a III-V epitaxial growth process or an etch clean process, and prior to additional processing. In one embodiment, a substrate processing apparatus is disclosed. The substrate processing apparatus includes a loadlock chamber, a support structure, and a gas distribution structure. The loadlock chamber has a body defining a volume therein. The support structure is disposed in the volume and has a plurality of support members. The gas distribution structure is disposed in the volume adjacent the support structure. Furthermore, the gas distribution structure includes a gas supply line and a plurality of distribution lines. The gas supply line is operatively connected to a gas source. Each distribution line is operatively connected to and extends from the gas supply line. At least one distribution line is disposed adjacent each support member, and each distribution line has a plurality of holes disposed therein. Moreover, each distribution line defines a plane. Each gas hole is angled toward a corresponding support member relative to the plane.

In another embodiment, a substrate processing apparatus is disclosed. The substrate processing apparatus includes a loadlock chamber, a support structure, and a gas distribution structure. The loadlock chamber has a body defining a volume therein. The support structure has a plurality of support members disposed in the volume. The gas distribution structure is disposed in the volume adjacent the support structure. The gas distribution structure includes a gas supply line and a plurality of distribution lines. The gas supply line is operatively connected to a first gas source and a second gas source. Each distribution line is operatively connected to and extends from the gas supply line. At least one distribution line is disposed adjacent to each support member, and each distribution line has a plurality of gas holes disposed therein.

In another embodiment, a substrate processing apparatus is disclosed. The substrate support apparatus includes a loadlock chamber, a support structure, and a gas distribution structure. The loadlock chamber has a body defining a volume therein. The support structure is disposed in the volume and has a plurality of support members. The gas distribution structure is disposed in the volume adjacent the support structure. The gas distribution structure includes a gas supply line operatively connected to an O₂ gas source and a N₂ gas source and a plurality of distribution lines. Each distribution line is operatively connected to and extends from the gas supply line. At least one distribution line is disposed adjacent each support member, and each distribution line has a plurality of gas holes disposed therein. Each gas hole is angled relative to a horizontal axis of the distribution line.

### BRIEF DESCRIPTION OF THE DRAWINGS

So that the manner in which the above recited features of the disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 schematically illustrates a side cross-sectional view of a load lock chamber for a gas purge system, according to one embodiment.

FIG. 2 schematically illustrates a top view of the load lock chamber of FIG. 1, according to one embodiment.

FIG. 3 schematically illustrates a front cross-sectional view of the load lock chamber of FIG. 1, according to one embodiment.

FIG. 4 schematically illustrates a top view of a distribution line, according to one embodiment.

FIG. 5 illustrates a schematic flow diagram of a method for controlling outgassing, according to one embodiment.

FIG. 6 illustrates a schematic flow diagram of a method for controlling outgassing after a III-V epitaxial process, according to one embodiment.

FIG. 7 illustrates a schematic flow diagram of a method for controlling outgassing, according to one embodiment.

FIG. 8 schematically illustrates a graph showing operations for controlling outgassing.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments disclosed herein generally relate to a system, method, and apparatus for controlling substrate outgassing such that hazardous gasses are eliminated from a surface of a substrate after a III-V epitaxial growth process or an etch clean process, and prior to additional processing. An oxygen containing gas is flowed to a substrate in a load lock chamber, and subsequently a non-reactive gas is flowed to the substrate in the load lock chamber. As such, hazardous gases and outgassing residuals are decreased and/or removed from the substrate such that further processing may be performed.

A “substrate” or “substrate surface,” as described herein, generally refers to any substrate surface upon which processing is performed. For example, a substrate surface may include silicon, silicon oxide, doped silicon, silicon germanium, germanium, gallium arsenide, glass, sapphire, and any other materials, such as metals, metal nitrides, metal alloys, and other conductive or semi-conductive materials, depending on the application. A substrate or substrate surface may also include dielectric materials such as silicon dioxide, silicon nitride, organosilicates, and carbon dopes silicon oxide or nitride materials. The term “substrate” may further include the term “wafer.” The substrate itself is not limited to any particular size or shape. Although the implementations described herein are generally made with reference to a round substrate, other shapes, such as polygonal, squared, rectangular, curved, or otherwise non-circular workpieces may be utilized according to the implementations described herein.

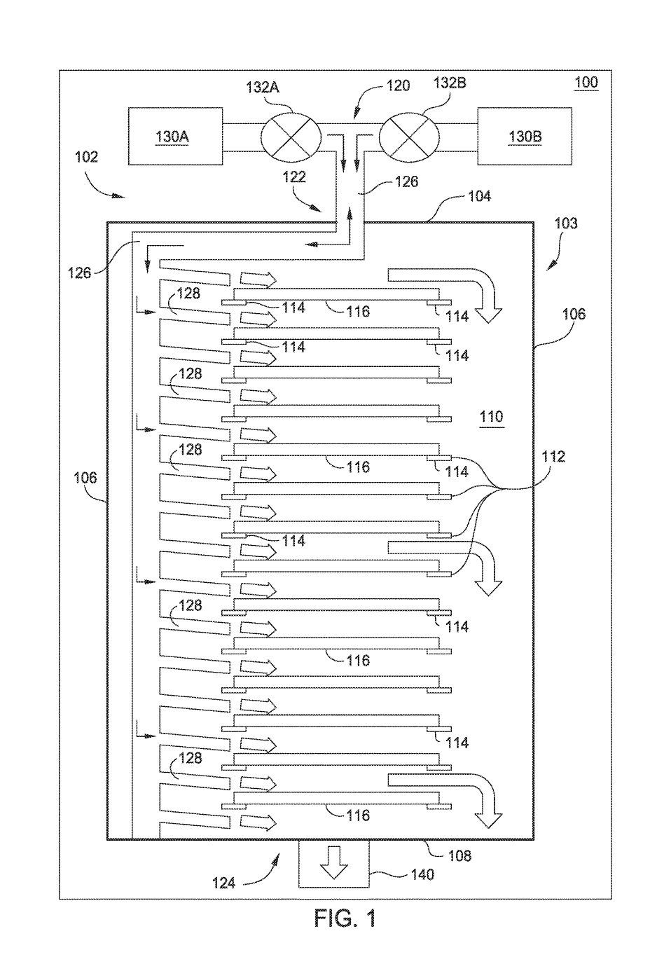

FIG. 1 schematically illustrates a simplified side cross-sectional view of a load lock chamber 102 for a gas purge system 100, according to one embodiment. The load lock chamber 102 has a body 103 defined by a lid 104, side walls 106, and a bottom wall 108. The body defines a volume 110 therein. In some embodiments, the load lock chamber 102 may be a substrate access chamber, or vice versa, as discussed supra. A support structure 112 is disposed in the volume 110 and includes a plurality of support members 114. Each support member 114 is configured to support a substrate 116 thereon. The support structure 112 may have one or more support members 114, and each support member 114 may hold and/or support a portion of the substrate 116 or the entire substrate. In certain embodiments, each support member 114 may contact the substrate 116 at or near the edge of the substrate 116 so as to not interfere with the processing of the substrate 116. The support structure 112 may be configured to hold and/or support, for example, twenty-five or more substrates in the body 103. In some embodiments, the plurality of support members 114 may each include a minimum contact surface (not shown). The minimum contact surface may include a plurality of raised surfaces, for examples three bumps, such that a substrate rests on each of the raised surfaces. In certain embodiments, the minimum contact surface may also include a mesh support disposed below, adjacent, and or in contact with the plurality of raised surfaces. The mesh support may be any gas transmissive structure, for example, a structure that allows gas to pass therethrough. The minimum contact surface may allow for processing of a bottom side of the substrate.

A gas distribution structure 120 is disposed in the volume 110. In some embodiments, the gas distribution structure 120 may also extend out of the volume 110 at a first end 122 and/or a second end 124 of the body. The gas distribution structure 120 is disposed adjacent to the support structure 112. The gas distribution structure 120 includes a gas supply line 126 and a plurality of distribution lines 128.

The gas supply line 126 is operatively connected to a first gas source 130A. In some embodiments, however, the gas supply line 126 is operatively connected to more than one gas source, such as a first gas source 130A and a second gas source 130B. In some embodiments, the first gas source 130A and/or the second gas source 1306 may be disposed outside of the volume 110, while in other embodiments, the first gas source 130A and/or the second gas source 130B may be disposed inside the volume 110. The gas supply line 126 is configured to deliver gas from a gas source into the volume 110. A first valve 132A is disposed between the first gas source 130A and the gas supply line 126. A second valve 132B is disposed between the second gas source 130B and the gas supply line 126. The flow of gas from the first gas source 130A may be controlled by a first valve 132A. The first valve 132A may be operatively connected to the gas supply line 126. The first valve 132A is configured to regulate the amount and/or flow of gas supplied by the first gas source 130A to the gas supply line 126. The flow of gas from the second gas source 130B may be controlled by a second valve 132B. The second valve 132B may be operatively connected to the gas supply line 126. The second valve 132B regulates the amount and/or flow of gas supplied by the second gas source 1306 to the gas supply line 126. In some embodiments, the first gas source 130A may be an oxygen containing gas source or a nitrogen containing gas source. In some embodiments, the second gas source 130B may be an oxygen containing gas source or a nitrogen containing gas source. Although two gas sources are shown, it is contemplated that any number of gas sources, containing any suitable gas, may be operatively connected to the gas supply line 126. Additionally, any of the gas distribution structure 120, the gas supply line 126, and/or the distribution lines may comprise a stainless steel material.

In certain embodiments, gas may flow from the first gas source 130A and/or the second gas source 130B to the gas supply line 126 upon an opening of the first valve 132A or the second valve 132B, respectively. In some embodiments, only the first valve 132A or only the second valve 132B may be opened at a time such that only one gas is flowed into the volume 110 at a time. However, in certain embodiments, multiple gases may be flowed into the volume 110 at the same time. For example, in some embodiments, both the first valve 132A and the second valve 132B may be opened at the same time. Gas may flow through the gas distribution structure 120 and into the volume 110 as shown by the arrows in FIG. 1. Upon exiting each distribution line 128 the gas may flow over and/or across each substrate 116. After flowing over and/or across each substrate 116, the gas may be directed toward the bottom wall 108 of the body 103. In some embodiments, a pump 140 may be disposed at or near the bottom wall 108 of the body 103. The pump 140 may be disposed in and/or create an opening in the bottom wall 108 such that the pump is configured to pump gas out of and remove gas from the body 103.

Furthermore, each of the gas distribution structure 120, the gas supply line 126, and/or each distribution line 128 may be pressurized to ensure the same or similar flow of gas on or across substrates disposed near the lid 104 of the body 103 as is flowed on or across substrates disposed near the bottom wall 108 of the body 103.

As discussed infra, a material is removed from a surface of the substrate 116 by reacting an oxygen containing gas with the surface of the substrate 116. Typically, a substrate access chamber, such as load lock chamber 102, maintains an inert environment. The flowing of the oxygen containing gas into the body 103 may expose each substrate 116 therein to the oxygen containing gas. As shown, oxygen containing gas may flow from the first gas source 130A and/or the second gas source 130B to the load lock chamber 102. Upon contacting the substrate 116, any residual arsenic related species on a surface of the substrate 116, as well as on the III-V surface, are oxidized. The arsenic residuals are broken down to either stable oxides and/or byproducts which have a high vapor pressure, and therefore evaporate quickly. As such, the deliberate pulsing and/or providing of the oxygen containing gas into the volume 110 may pre-remove arsenic in a controlled manner in order to appropriately abate the arsenic.

Flowing an oxygen containing gas into the load lock chamber 102 may allow for stable oxides to form on the surface of the substrate 116. Also, the oxygen containing gas may allow high vapor pressure byproducts may be removed from the substrate 116. Moreover, oxidation may have various effects on the substrate 116. The oxidation may break the bond of the arsenic species (for example between arsenic and OH groups) to carbon to form arsenic oxide which may leave the surface of the substrate more quickly.

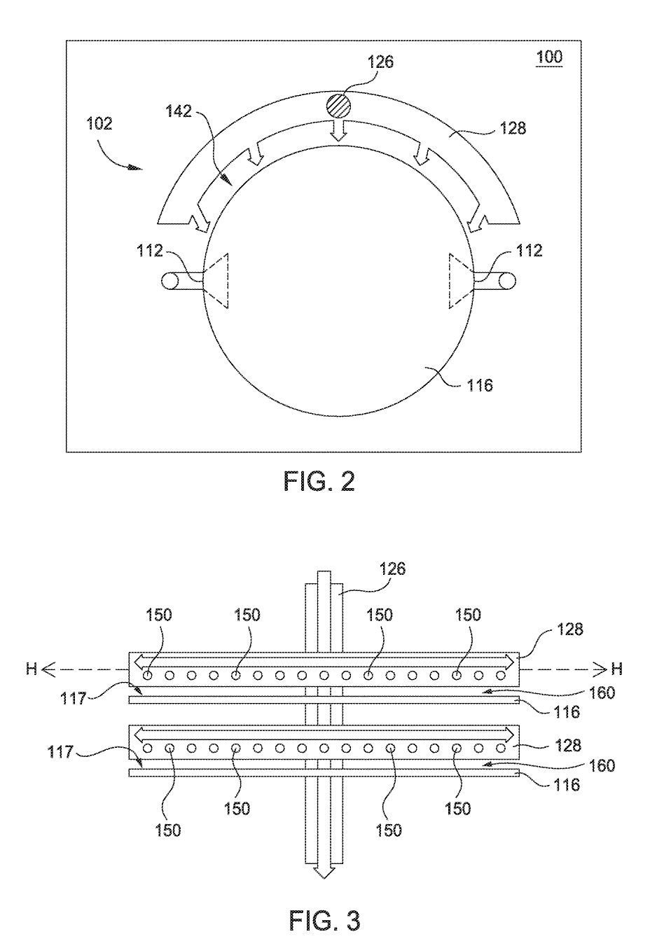

FIG. 2 schematically illustrates a top view of the load lock chamber 102 of FIG. 1, according to one embodiment. As shown, at least one distribution line 128 is disposed adjacent each support member 114. Each distribution line 128 is operatively connected to the gas supply line 126. In some embodiments, each distribution line 128 extends from the gas supply line 126. As shown in FIG. 2, at least one distribution line 128 is disposed adjacent each support member 114. Furthermore, in certain embodiments, the gas supply line 126 may run through each distribution line 128. In some embodiments, the gas supply line 126 is disposed through the center of each distribution line 128, while in other embodiments, the gas supply line 126 may be disposed through any section of each distribution line 128, for example, near a distal end of the distribution line 128.

Each distribution line 128 has an arcuate shape, such that the distribution line conforms to the approximate shape of at least a portion of the substrate 116. In some embodiments, the distribution line 128 may have a radius of between about two inches and about twenty inches, for example between about four inches and about twelve inches. In certain embodiments, each distribution line 128 may have an angular extent of between about 90 degrees and about 180 degrees, for example between about 100 degrees and about 150 degrees. In some embodiments, however, each distribution line 128 may have a V-shape, a C-shape, a square shape, a rectangular shape, or any other suitable shape, such that the distribution line 128 is configured to distribute gas along and/or across a surface of the substrate 116. Each distribution line 128 may be a circular tube, however, it is contemplated that any shape distribution line may be suitably utilized.

Each distribution line 128 may be disposed adjacent, immediately next two, and/or proximate each substrate 116 held by each support member 114. A gap 142 may be disposed between each distribution line 128 and each substrate 116. In some embodiments, the gap 142 between each distribution line 128 and each substrate 116 may be between about 1/16 inch and about one inch, for example between about ⅛ inch and about ¼ inch.

FIG. 3 schematically illustrates a front cross-sectional view of the load lock chamber 102 of FIG. 1, according to one embodiment. Each distribution line 128 has a plurality of gas holes 150 disposed therein. In some embodiments, each distribution line 128 comprises between about two gas holes 150 and about 50 gas holes 150, for example between about eight gas holes 150 and about 20 gas holes 150. It is contemplated, however, that each distribution line 128 may include any suitable number of gas holes 150.

Each gas hole 150 has a diameter between about 1/64 inch and about ½ inch, for example between about 1/32 inch and about ¼ inch. Each of the plurality of gas holes 150 may be uniformly distributed along each distribution line 128, thus creating an equal amount of spacing between each gas hole 150. However, in some embodiments, each of the plurality of gas holes 150 may be non-uniformly distributed along each distribution line 128. As such, the spacing between each gas hole 150 may vary between each gas hole. Therefore, in some embodiments, a higher or lower concentration of gas holes 150 may be disposed, for example, near the center of each distribution line 128 and/or near the distal end of each distribution line 128.

With reference to both FIG. 2 and FIG. 3, each distribution line 128 may be disposed at or above a top surface 117 of each substrate 116. In some embodiments, a gap 160 may be disposed between the top surface 117 of each substrate 116 and each respective distribution line 128. The gap 160 may be between about 1/32 inch and about ½ inch, for example between about 1/16 inch and about ¼ inch. Each distribution line 128 defines a plane. Each gas hole 150 may be disposed along the plane. By way of example only, in some embodiments, each distribution line 128 may define a horizontal plane H. By way of continued example, each gas hole 150 may be disposed along the horizontal plane H, such as above the horizontal plane H, or below the horizontal plane H. Each gas hole 150 has a gas flow axis that forms an angle between about five degrees and about twenty-five degrees with the plane. In some embodiments, each gas hole 150 may be angled downward or upward relative to the horizontal plane H of each distribution line 128. In some embodiments, each gas hole 150 is angled downward or upward relative to the horizontal plane H at an angle between about two degrees and about forty-five degrees, such as between about five degrees and about twenty-five degrees. In some embodiments, however, each gas hole 150 may be angled upward relative to the horizontal plane, for example, during processing of a bottom side of the substrate 116. The angling of each gas hole 150 toward the top surface 117 or bottom surface of each substrate 116 directs flow of the gas to the top surface 117 or bottom surface of each substrate 116. As discussed supra, when oxygen gas is flowed across each substrate 116, outgassing species are efficiently and effectively carried away from the substrate 116. Furthermore, in some embodiments, the flow rate of the gas exiting the gas holes 150 may range from subsonic to supersonic.

With further reference to both FIG. 2 and FIG. 3, each gas hole 150 may be drilled at an angle normal to the distribution line 128, or, in some embodiments, as an angle non-normal to the distribution line 128. In certain embodiments, certain gas holes 150 may be drilled at an angle normal to the distribution line 128 while other gas holes 150 may be drilled at an angle non-normal to the distribution line 128. Also, certain gas holes 150 may be drilled outward on each distribution line 128 to ensure gas coverage of the entire surface of the substrate 116. As shown in FIG. 2, the gas holes 150 proximate the distal end of the distribution line may be configured to direct gas at an angle non-normal to the distribution line 128. As such, the angle non-normal to the distribution line 128 may increase for subsequent gas hole 150 closer to the distal ends of the distribution line 128. As further shown in FIG. 2, in some embodiments, gas holes 150 disposed closer to the center of the distribution line 128 may be drilled at an angle subsequently closer to an angle normal to the distribution line 128. As such, in certain embodiments, and as shown in FIG. 2 and FIG. 3, a first sub-plurality of the plurality of gas holes 150 may be disposed at an angle normal to the distribution line and a second plurality of the plurality of gas holes 150 may be disposed at an angle non-normal to the distribution line 128.

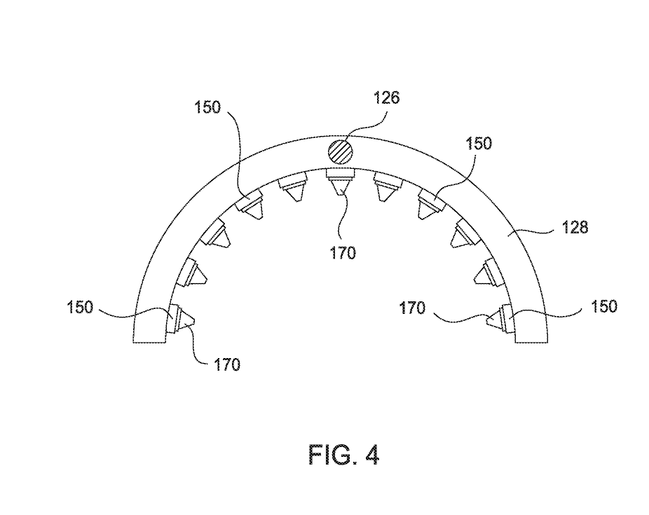

FIG. 4 schematically illustrates an embodiment of the distribution line 128 which includes a plurality of nozzles 170 operatively connected to each gas hole 150. As described supra, each gas hole 150 may be angled, and as such, each respective nozzle 170 may also be angled. However, in some embodiments, each gas hole may be drilled at an angle normal to the distribution line 128, and each respective nozzle may be movably positioned in order to direct the flow of gas in the proper direction across the substrate 116.

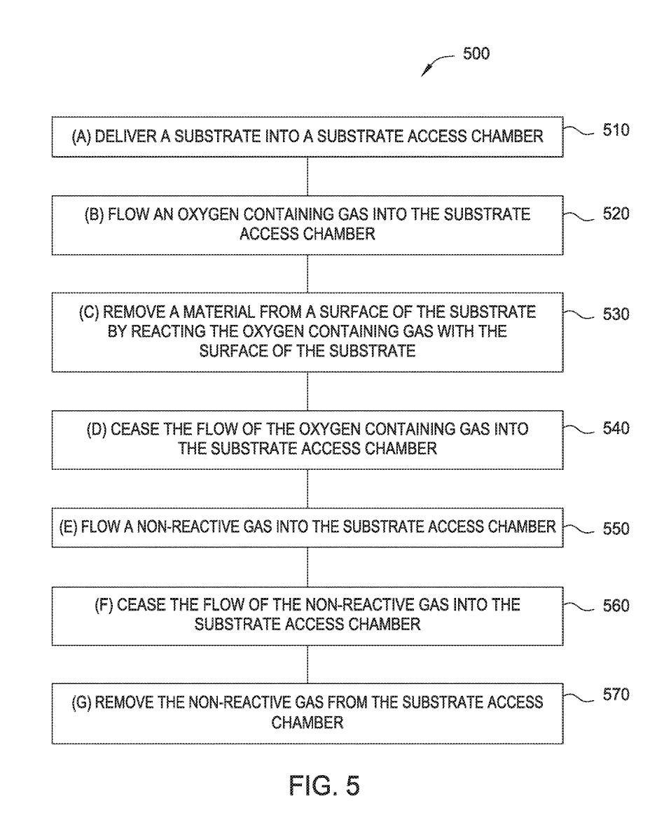

FIG. 5 is a schematic flow diagram of a method 500 for controlling outgassing. The method 500 provides operations for reducing outgassing. Substrate outgassing generally relates to the releasing of a gas or vapor product from the substrate or from a surface of the substrate. Controlling outgassing relates to reducing and/or eliminating residual outgassed materials, for example, arsenic, from a substrate prior to transferring the substrate for downstream processing.

At operation 510, a substrate is delivered into a substrate access chamber. In some embodiments, the substrate access chamber may be a load lock chamber and/or a FOUP (front opening unified pod). In some embodiments, each substrate may be transferred to the substrate access chamber in a non-reactive gas, for example, after a III-V epitaxial growth process and/or after a III-V etch process.

At operation 520, an oxygen containing gas is flowed into the substrate access chamber and, at operation 530, a material is removed from a surface of the substrate by reacting the oxygen containing gas with the surface of the substrate. Typically, a substrate access chamber maintains an inert environment. The flowing of the oxygen containing gas into the substrate access chamber may expose the substrate therein to the oxygen containing gas. The flowing of the oxygen containing gas into the substrate access chamber may occur via a conduit coupled to an oxygen containing gas source and to the substrate access chamber. The oxygen containing gas may flow from the oxygen containing gas source to the substrate access chamber. Upon contacting the substrate, any residual arsenic related species on a surface of the substrate, as well as on the III-V surface, are oxidized. The arsenic residuals are broken down to either stable oxides and/or byproducts which have a high vapor pressure, and therefore evaporate quickly. As such, the deliberate pulsing and/or providing of the oxygen containing gas into the substrate access chamber may pre-remove arsenic in a controlled manner in order to appropriately abate the arsenic.

In some embodiments, the oxygen containing gas is oxygen. It is contemplated that any amount of oxygen containing gas may be flowed into the substrate access chamber, however, in some embodiments, between about 5 sccm and about 1200 sccm of the oxygen containing gas is flowed into the substrate access chamber.

The oxygen containing gas is flowed into the substrate access chamber for between about one second and about 60 seconds, for example, between about one second and about 30 seconds, such as about 10 seconds. Furthermore, the oxygen containing gas is flowed into the substrate access chamber at a first pressure (P1). In some embodiments, the first pressure (P1) is between about 60 Torr and about 220 Torr, for example between about 80 Torr and about 200 Torr.

Flowing the oxygen containing gas into the substrate access chamber may allow for stable oxides to form on the surface of the substrate. Also, the oxygen containing gas may allow high vapor pressure byproducts to be removed from the substrate.

Moreover, oxidation may have various effects on the substrate. The oxidation may break the bond of the arsenic species (for example between arsenic and OH groups) to carbon to form arsenic oxide which may leave the surface of the substrate more quickly.

At operation 540, the flow of the oxygen containing gas into the substrate access chamber is ceased.

At operation 550, a non-reactive gas is flowed into the substrate access chamber. The non-reactive gas is flowed into the substrate access chamber for between about 30 seconds and about 400 seconds, for example, between about 60 seconds and about 300 seconds. In some embodiments, the non-reactive gas is flowed into the substrate access chamber at a second pressure (P2). Furthermore, the second pressure (P2) is greater than the first pressure (P1), discussed supra. In some embodiments, the second pressure (P2) is above about 180 Torr, for example, above about 200 Torr. It is contemplated, however, that the second pressure (P2) may be any pressure greater than the first pressure (P1). The non-reactive gas may include a helium-containing gas, a hydrogen-containing gas, a nitrogen-containing gas, and/or an argon-containing gas, among others. In some embodiments, the non-reactive gas is N₂. The flowing of the non-reactive gas into the substrate access chamber may occur after the flowing of the oxygen containing gas into the substrate access chamber. The flowing of the non-reactive gas after oxidation drives down outgassing towards to the zero ppb level. The zero ppb level means that the outgassing of toxic species, for example, arsenic, is undetectable.

At operation 560, the flow of the non-reactive gas into the substrate access chamber is ceased.

At operation 570, the non-reactive gas is removed from the substrate access chamber, for example, via a pump cycle. The removing of the non-reactive gas from the substrate access chamber is at a third pressure (P3). The third pressure is less than the first pressure (P1). In some embodiments, the third pressure is less than about 1 Torr. The third pressure (P3) is lower than the second pressure (P2) and/or the first pressure (P1) during the removal of the non-reactive gas such that when the non-reactive gas is reinserted into the substrate access chamber a strong dilution is provided for. Furthermore, the first pressure (P1) being less than the second pressure (P2) provides for efficiency benefits to improve the reaction rate.

In some embodiments, operation 550, operation 560, and/or operation 570 may be repeated for at least one additional cycle after an initial completion of operation 570. By repeating the flowing of the non-reactive gas into the substrate access chamber, ceasing the flow of the non-reactive gas into the substrate access chamber, and/or removing the non-reactive gas from the substrate access chamber, outgassing is further driven down towards the zero ppb level. Testing has been completed and results indicate that one oxidation operation, such as operation 520, operation 530, and operation 540, and three non-reactive gas cycles, such as operation 550, operation 560, and operation 570, reduce outgassing to zero ppb.

In some embodiments, after outgassing has been reduced, the substrate may be transferred to a FOUP (front opening unified pod) for further down-stream processing.

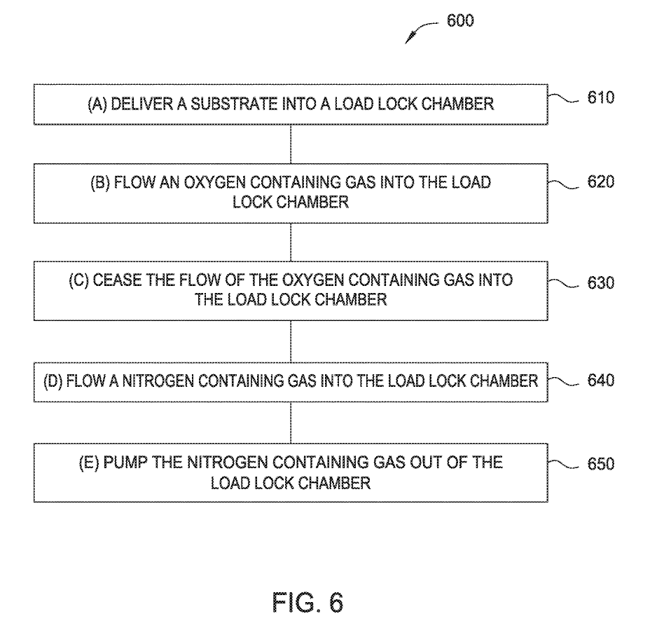

FIG. 6 is a schematic flow diagram of a method 600 for controlling outgassing after a III-V epitaxial process. The method 600 provides a solution for reducing outgassing.

At operation 610, a substrate is delivered to a load lock chamber.

At operation 620, an oxygen containing gas is flowed into the load lock chamber. The flowing of the oxygen containing gas into the load lock chamber may expose the substrate therein to the oxygen containing gas. Upon contacting the substrate, any residual arsenic related species on a surface of the substrate, as well as on the III-V surface, is oxidized. The arsenic residuals are broken down to either stable oxides and/or byproducts which have a high vapor pressure, and therefore evaporate quickly. As such, the deliberate pulsing and/or providing of the oxygen containing gas into the load lock chamber may pre-remove arsenic in a controlled manner in order to appropriately abate the arsenic.

In some embodiments, the oxygen containing gas is oxygen. It is contemplated that any amount of oxygen containing gas may be flowed into the load lock chamber, however, in some embodiments, between about 5 sccm and about 1200 sccm of the oxygen containing gas is flowed into the load lock chamber.

The oxygen containing gas is flowed into the load lock chamber for between about one second and about 60 seconds, for example, between about one second and about 30 seconds, such as about 10 seconds. Furthermore, the oxygen containing gas is flowed into the load lock chamber at a first pressure (P1). In some embodiments, the first pressure (P1) is between about 60 Torr and about 220 Torr, for example between about 80 Torr and about 200 Torr.

Flowing the oxygen containing gas into the load lock chamber may allow for stable oxides to form on the surface of the substrate. Also, the oxygen containing gas may allow high vapor pressure byproducts to be removed from the substrate.

At operation 630, the flow of the oxygen containing gas into the load lock chamber is ceased.

At operation 640, a nitrogen containing gas is flowed into the load lock chamber. The nitrogen containing gas is flowed into the load lock chamber for between about 30 seconds and about 400 seconds, for example, between about 60 seconds and about 300 seconds. In some embodiments, the nitrogen containing gas is flowed into the load lock chamber at a second pressure (P2). Furthermore, the second pressure (P2) is greater than the first pressure (P1), discussed supra. In some embodiments, the second pressure (P2) is above about 180 Torr, for example, above about 200 Torr. In some embodiments, the nitrogen containing gas is N₂. The flowing of the nitrogen containing gas into the load lock chamber may occur after the flowing of the oxygen containing gas into the load lock chamber. The flowing of nitrogen containing gas after oxidation drives down outgassing towards to the zero ppb level.

At operation 650, the nitrogen containing gas is pumped out of the load lock chamber. The removing of the nitrogen containing gas from the load lock chamber is at a third pressure (P3). The third pressure is less than the first pressure (P1). In some embodiments, the third pressure is less than about 1 Torr. The third pressure (P3) is lower than the second pressure (P2) and/or the first pressure (P1) during the removal of the nitrogen containing gas such that when the nitrogen containing gas is reinserted into the load lock chamber a strong dilution is provided for. Furthermore, the first pressure (P1) being less than the second pressure (P2) provides for efficiency benefits to improve the reaction rate.

The method 600 may also include repeating the flowing of the nitrogen containing gas into the load lock chamber as in operation 640 and/or the pumping of the nitrogen-containing gas out of the load lock chamber as in operation 650, for at least one additional cycle. By repeating the flowing of the nitrogen containing gas into the load lock chamber and removing the nitrogen containing gas from the load lock chamber, outgassing is further driven down towards the zero ppb level. Testing has been completed and results indicate that one oxidation operation and three nitrogen containing gas cycles reduce outgassing to zero ppb. In some embodiments, the method 600 may also include removing a material from a surface of the substrate by reacting the oxygen containing gas with the surface of the substrate. In some embodiments, after outgassing has been reduced, the substrate may be transferred to a FOUP (front opening unified pod) for further down-stream processing.

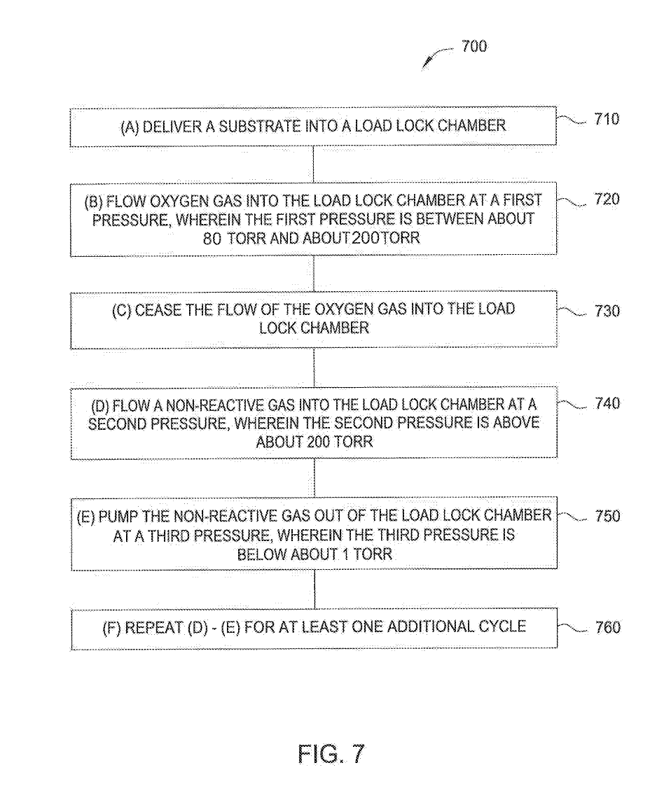

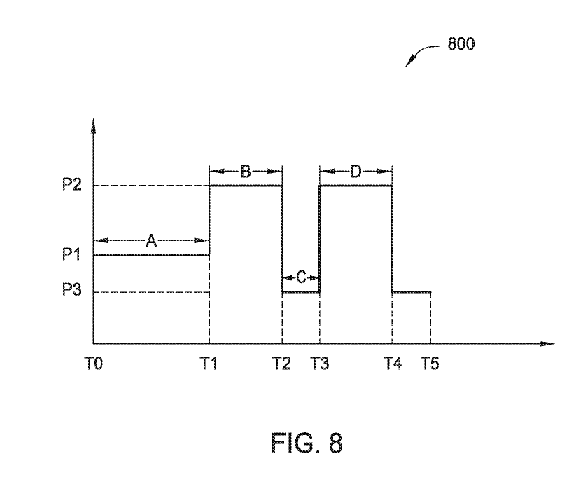

FIG. 7 is a schematic flow diagram of a method 700 for controlling outgassing. The method 700 provides a solution for reducing outgassing.

At operation 710, a substrate is delivered to a load lock chamber.

At operation 720, oxygen gas is flowed into the load lock chamber at a first pressure (P1). The first pressure (P1) is between about 30 Torr and about 300 Torr. The flowing of the oxygen gas into the load lock chamber may expose the substrate therein to the oxygen gas. Upon contacting the substrate, any residual arsenic related species on a surface of the substrate, as well as on the III-V surface, are oxidized. The arsenic residuals are broken down to either stable oxides and/or byproducts which have a high vapor pressure, and therefore evaporate quickly. As such, the deliberate pulsing and/or providing of the oxygen gas into the load lock chamber may pre-remove arsenic in a controlled manner in order to appropriately abate the arsenic.

It is contemplated that any amount of oxygen gas may be flowed into the load lock chamber, however, in some embodiments, between about 5 sccm and about 1200 sccm of the oxygen gas is flowed into the load lock chamber.

The oxygen gas is flowed into the load lock chamber for between about one second and about 60 seconds, for example, between about one second and about 30 seconds, such as about 10 seconds. Furthermore, the oxygen gas is flowed into the load lock chamber at a first pressure (P1). In some embodiments, the first pressure (P1) is between about 30 Torr and about 300 Torr, for example between about 80 Torr and about 200 Torr.

Flowing the oxygen gas into the load lock chamber may allow for stable oxides to form on the surface of the substrate. Also, the oxygen gas may allow high vapor pressure byproducts to be removed from the substrate.

At operation 730, the flow of the oxygen gas into the load lock chamber is ceased.

At operation 740, a non-reactive gas is flowed into the load lock chamber at a second pressure (P2). The second pressure (P2) is above about 180 Torr, for example above about 200 Torr. The non-reactive gas is flowed into the load lock chamber for between about 30 seconds and about 400 seconds, for example, between about 60 seconds and about 300 seconds. In some embodiments, the non-reactive gas is N₂. The flowing of the non-reactive gas into the load lock chamber may occur after the flowing of the oxygen gas into the load lock chamber. The flowing of the non-reactive gas after oxidation drives down outgassing towards to the zero ppb level. The zero ppb level means that the outgassing of toxic species, for example, arsenic, is undetectable.

At operation 750, the non-reactive gas is pumped out of the load lock chamber at a third pressure (P3). The third pressure is below about 1 Torr. The third pressure (P3) is lower than the second pressure (P2) and/or the first pressure (P1) during the removal of the non-reactive gas such that when the non-reactive gas is reinserted into the load lock chamber a strong dilution is provided for. Furthermore, the first pressure (P1) being less than the second pressure (P2) provides for efficiency benefits to improve the reaction rate.

At operation 760, operation 740 and operation 750 are repeated for at least one additional cycle. By repeating the flowing of the non-reactive gas into the load lock chamber and removing the non-reactive gas from the load lock chamber, outgassing is further driven down towards the zero ppb level. Testing has been completed and results indicate that one oxidation operation and three non-reactive gas cycles reduce outgassing to zero ppb. In some embodiments, the method 700 may also include removing a material from a surface of the substrate by reacting the oxygen containing gas with the surface of the substrate. In some embodiments, after outgassing has been reduced, the substrate may be transferred to a FOUP (front opening unified pod) for further down-stream processing.

FIG. 8 schematically illustrates a graph 800 showing operations for controlling outgassing, as discussed supra. As shown, an oxygen containing gas is flowed into the load lock chamber at a first pressure (P1) in the section marked A, between time T0 and time T1. The span of time between T0 and T1 may be between about one second and about 60 seconds. At time T1 the flowing of the oxygen containing gas into the load lock chamber is ceased. The non-reactive gas is flowed into the load lock chamber at a second pressure (P2) in the section marked B, between time T1 and time T2. The span of time between T1 and T2 may be between about 30 seconds and about 400 seconds. At time T2 the flowing of the non-reactive gas into the load lock chamber is stopped. Furthermore, the non-reactive gas is pumped out of the load lock chamber at a third pressure (P3) between time T2 and time T3 as shown in the section marked C. The span of time between T2 and T2 may be between about 30 seconds and about 400 seconds. A subsequent non-reactive gas flow and removal cycle may occur in the section marked D between time T3 and time T5.

Testing has been completed and results indicate that after an exposure to an oxygen containing gas residual arsenic related species on the substrate and/or on the surface of the substrate, as well as on the III-V surface, are oxidized. The arsenic residuals are broken down to either stable oxides or byproducts which have high vapor pressure and evaporate quickly. Also, after oxidation, the non-reactive gas pump/purge cycle is completed, thus driving down outgassing to zero ppb. Results indicate that after one oxidation and three non-reactive gas pump/purge cycles, outgassing was reduced to zero ppb, thus leaving no outgassing residuals and further improving throughput.

Benefits of the present disclosure include improved substrate throughput, as well as substrates in which residual arsenic outgassing gasses are eliminated before transfer to a FOUP. Furthermore, fume hoods are not necessary to control outgassing. Outgassing is controlled and removed prior to subsequent processes between chambers and/or tools.

Additional benefits include reduced contaminations and cross-contaminations. Also, the present disclosure may be applied to all arsenic and/or phosphate implantations, and is not limited to III-V implantations.

To summarize, the embodiments disclosed herein relate to a system, method, and apparatus for controlling substrate outgassing such that hazardous gasses are eliminated from a surface of a substrate after a III-V epitaxial growth process or an etch clean process, and prior to additional processing. An oxygen containing gas is flowed to a substrate in a load lock chamber, and subsequently a non-reactive gas is flowed to the substrate in the load lock chamber. As such, hazardous gases and outgassing residuals are decreased and/or removed from the substrate such that further processing may be performed.

While the foregoing is directed to embodiments of the present disclosure, other and further embodiments of the disclosure may be devised without departing from the basic scope thereof, and the scope thereof is determined by the claims that follow.

What is claimed is:

1. A substrate processing apparatus, comprising:
a loadlock chamber having a body defining a volume therein;
a support structure disposed in the volume, the support structure having a plurality of support members; and
a gas distribution structure disposed in the volume adjacent the support structure, the gas distribution structure comprising:
a gas supply line operatively connected to a gas source; and
a plurality of distribution lines, wherein each distribution line is operatively connected to and extends from the gas supply line, wherein at least one distribution line is disposed adjacent to each support member, wherein each distribution line has a plurality of gas holes disposed therein, wherein each distribution line defines a plane, and wherein each gas hole is angled toward a corresponding support member relative to the plane.

2. The substrate processing apparatus of claim 1, wherein each distribution line is an arcuate distribution line having a radius between about four inches and about twelve inches.

3. The substrate processing apparatus of claim 2, wherein each distribution line has an angular extent between about 100 degrees and about 150 degrees.

4. The substrate processing apparatus of claim 1, wherein each gas hole is disposed at the plane of each distribution line.

5. The substrate processing apparatus of claim 1, wherein each gas hole has a gas flow axis that forms an angle between about five degrees and about twenty-five degrees with the plane.

6. The substrate processing apparatus of claim 1, wherein each gas hole has a diameter between about 0.03125 inch and about 0.25 inch.

7. The substrate processing apparatus of claim 1, wherein the plurality of gas holes of each distribution line are uniformly distributed.

8. The substrate processing apparatus of claim 1, wherein the plane is a horizontal plane, and wherein each gas hole is angled downward relative to the horizontal plane.

9. The substrate processing apparatus of claim 1, wherein a first sub-plurality of the plurality of gas holes are disposed at an angle normal to the distribution line, and wherein a second sub-plurality of the plurality of gas holes are disposed at an angle non-normal to the distribution line.

10. The substrate processing apparatus of claim 1, wherein each support member is configured to support a substrate.

11. The substrate processing apparatus of claim, further comprising a valve disposed between the gas source and the gas supply line.

12. The substrate processing apparatus of claim 1, further comprising a plurality of nozzles, wherein each nozzle is operatively connected to one gas hole.

13. The substrate processing apparatus of claim 1, wherein the gas source is an oxygen containing gas source or a nitrogen containing gas source.

14. A substrate processing apparatus, comprising:
a loadlock chamber having a body defining a volume therein;
a support structure disposed in the volume, the support structure having a plurality of support members; and
a gas distribution structure disposed in the volume adjacent the support structure, the gas distribution structure comprising:
a gas supply line operatively connected to a first gas source and a second gas source; and
a plurality of distribution lines, wherein each distribution line is operatively connected to and extends from the gas supply line, wherein at least one distribution line is disposed adjacent each support member, and wherein each distribution line has a plurality of gas holes disposed therein.

15. The substrate processing apparatus of claim 14, wherein each distribution line is an arcuate distribution line having a radius between about four inches and about twelve inches and an angular extent between about 100 degrees and about 150 degrees.

16. The substrate processing apparatus of claim 14, wherein each distribution line defines a horizontal plane and each gas hole is angled relative to the horizontal plane at an angle between about five degrees and about twenty-five degrees.

17. The substrate processing apparatus of claim 14, wherein the gas supply line is disposed along a horizontal axis and each distribution line is angled relative to the horizontal axis.

18. The substrate processing apparatus of claim 14, wherein the first gas source is an oxygen gas containing gas source and the second gas source is a nitrogen containing gas source.

19. The substrate processing apparatus of claim 14, wherein a first sub-plurality of the plurality of gas holes are disposed at an angle normal to the distribution line, and wherein a second sub-plurality of the plurality of gas holes are disposed at an angle non-normal to the distribution line.

20. A substrate processing apparatus, comprising:
a loadlock chamber having a body defining a volume therein;
a support structure disposed in the volume, the support structure having a plurality of support members;
a gas distribution structure disposed in the volume adjacent the support structure, the gas distribution structure comprising:
a gas supply line operatively connected to an O₂ gas source and a N₂ gas source;
a plurality of distribution lines, wherein each distribution line is operatively connected to and extends from the gas supply line, wherein at least one distribution line is disposed adjacent each support member, wherein each distribution line has a plurality of gas holes disposed therein, and wherein each gas hole is angled toward a corresponding support member.
